(19) United States
(12) Patent Application Publication
(10) Pub. No.: US 2015/0189753 A1
(43) Pub. Date: Jul. 2, 2015

(54) STRESS-TOLERANT INTERCONNECTIONS FOR CONNECTIVITY IN WEARABLE ELECTRONICS PLATFORMS

(71) Applicants: Dileep Goyal, Fremont, CA (US); Mihai Ionescu, Santa Cruz, CA (US); Hari N. Chakravarthula, San Jose, CA (US)

(72) Inventors: Dileep Goyal, Fremont, CA (US); Mihai Ionescu, Santa Cruz, CA (US); Hari N. Chakravarthula, San Jose, CA (US)

(73) Assignee: AliphCom, San Francisco, CA (US)

(21) Appl. No.: 14/144,516

(22) Filed: Dec. 30, 2013

(51) Int. Cl. H05K 1/14; H05K 3/36; H01B 7/06

(52) U.S. Cl. CPC H05K 1/142; H01B 7/06; H05K 3/36; H05K 2201/09872

(57) ABSTRACT

Embodiments relate generally to wearable electrical and electronic hardware, computer software, wired and wireless network communications, and to wearable/mobile computing devices configured to facilitate communication among electronic devices, including mobile phones and media devices that present audio and/or video content. More specifically, disclosed are wearable systems, platforms and methods for providing stress-tolerant interconnections to enhance signal connectivity reliability in a wearable device. In various embodiments, a wearable electronics platform can include circuit substrates and interconnect portions disposed coextensive with a longitudinal surface between the circuit substrates. An interconnection portion can include conductors having one or more stress-relief features, and an elastic material encapsulating the conductors. In some examples, the longitudinal surface including the interconnects and the circuit substrates can be configured to substantially encircle an axis. The axis can coincide with a body part or an appendage, such as a wrist.

### FIELD

Embodiments relate generally to wearable electrical and electronic hardware, computer software, wired and wireless network communications, and to wearable/mobile computing devices configured to facilitate communication among electronic devices, including mobile phones and media devices that present audio and/or video content. More specifically, disclosed are wearable systems, platforms and methods for providing stress-tolerant interconnections to enhance signal connectivity reliability in a wearable device.

### BACKGROUND

Wearable computing devices, such as those that include processors, memory, and a variety of sensors, are subject to many different stresses and strains when worn by a user. Wearable computing devices also are subject to harsh and sometimes inhospitable environments in which the wearer is performing an activity. In particular, wearable devices worn at or about a user's wrist, is subject to more motion than at the wearer's torso, and more stresses and strains as well. For example, a wrist-worn wearable device can experience stresses and strains when a user reaches into a pant pocket, or when the user bumps against a wall during an activity or experiences any other impulse-like forces (e.g., striking a baseball, a golf ball, a hockey puck, and the like, or catching a baseball, football, and the like). Further, wearable device can experience stresses and strains when the user places the wearable device on an appendage, or when the user removes the wearable device.

Size is a design parameter to which most wearable devices are created. It is a goal for wearable devices to be as minimally intrusive to the wearer, while providing sufficient computing resources to provide the user activity information, physiological information, and other types of information.

While functional, traditional devices and solutions to wearable device design and fabrication are not well-suited for providing reliable signal connectivity for a wearable computing device. Conventionally, the miniaturization of printed circuit boards, wiring, and electronic devices generally have contributed, at least in some cases, to less reliable signal connectivity within traditional wearable devices. For example, common stresses and strains can cause a break in the wiring that renders the wearable devices inoperable.

Thus, what is needed is a solution for facilitating signal and electronic conductivity without the limitations of conventional techniques.

### BRIEF DESCRIPTION OF THE DRAWINGS

Various embodiments or examples (“examples”) of the invention are disclosed in the following detailed description and the accompanying drawings:

FIG. 1 illustrates an example of a wearable electronics platform, according to some embodiments;

FIGS. 2A and 2B depict other examples of wearable computing devices in which wearable electronics platforms can be disposed, according to some embodiments;

FIG. 2C is a side view that depicts a wearable computing device including an arrangement of interconnect portions and circuit substrates, according to some examples;

FIG. 3 illustrates an example of an interconnect portion, according to some embodiments;

FIGS. 4A to 4D depict examples of stress-relief features, according to some embodiments;

FIGS. 5A to 5B depict examples interconnect portions having stress-relief features, according to some examples;

FIGS. 6A and 6B depict a specific example of a wearable electronics platform, according to some examples;

FIGS. 7A and 7B depict specific examples of wearable electronics platforms encapsulated in an elastic material, according to some examples;

FIG. 8 illustrates an example of a flow for generating flexible interconnections for a wearable device, according to some embodiments; and

FIG. 9 depicts an antenna implementing one or more conductors including stress-relief features, according to various examples.

### DETAILED DESCRIPTION

Various embodiments or examples may be implemented in numerous ways, including as a system, a process, an apparatus, a user interface, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For clarity, technical material that is known in the technical fields related to the examples has not been described in detail to avoid unnecessarily obscuring the description.

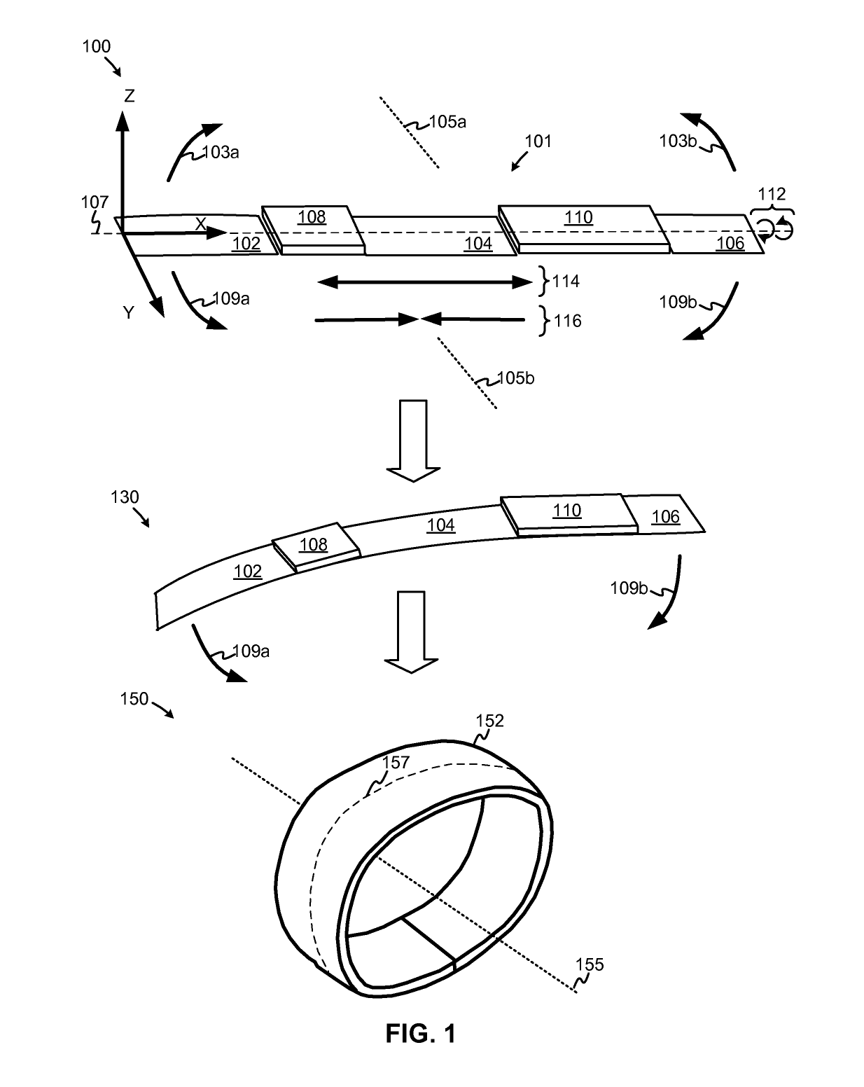

FIG. 1 illustrates an example of a wearable electronics platform, according to some embodiments. Diagram 100 depicts a wearable electronics platform 101 including interconnect portions 102, 104, and 106, and circuit substrates 108 and 110. To illustrate examples of the stresses, strains and forces applied to wearable electronics platform 100, interconnect portions 102, 104, and 106, and circuit substrates 108 and 110 are shown to be disposed in, or on, a longitudinal surface (e.g., the X-Y plane) that includes a longitudinal axis 107. More or fewer interconnect portions and circuit substrates are possible. As used herein, the term “longitudinal” can refer conceptually, at least in some embodiments, to a plane, surface, or line that extends along an elongated dimension or otherwise runs lengthwise for wearable electronics platform 101. As such, the term “longitudinal” is not limited to a plane in two dimensions, but rather can describe a surface that, for example, has curved portions relative to a point or axis in space.

As shown, interconnect portions 102, 104, and 106, and circuit substrates 108 and 110 can be subject to stresses, strains, and forces along a longitudinal axis 107. For example, wearable electronics platform 101 can experience strain when compressive forces 116 are applied to one or more ends. Wearable electronics platform 101 can also experience strain when tensile forces 114 (e.g., decompressive or stretching forces) are applied to one or more ends. Additionally, wearable electronics platform 101 and its constituent components can experience torsional forces in directions 112, such as when one end is twisted in an opposite direction 112 that other. Further, wearable electronics platform 101 can be subject to bending forces 103a and 103b, which cause wearable electronics platform 101 to bend about axis 105a. Wearable electronics platform 101 also can be subject to bending forces 109a and 109b, which cause wearable electronics platform 101 to bend about axis 105ba. Axes 105a and 105b can coincide with an orientation of an appendage, such as a forearm, a forehead, an ankle, or a wrist.

According to some embodiments, circuit substrates 108 and 110 are configured to accept a number of electronic devices, such as a processor, a memory, sensors, and the like. In some cases, circuit substrates 108 and 110 can be composed of rigid or semi-rigid materials, such as laminates, printed circuit board materials (e.g., FR-4 composite materials, etc.), or the like. According to some embodiments, circuit substrates 108 and 110 are less flexible than interconnect portions 102, 104, and 106. As shown, interconnect portions 102, 104, and 106 are disposed coextensive with a longitudinal surface (e.g., in the X-Y plane) between circuit substrates. According to some embodiments, interconnect portion 104 can include conductors extending between circuit substrate 108 and circuit substrate 110. The conductors can include one or more stress-relief features (not shown) and/or can be encapsulated in an elastic material (not shown), either or both of which facilitate relief to stresses and strains applied to wearable electronics platform 101. In some examples, the stress-relief features and/or elastic material can provide, whether individually or in combination, stress relief responsive to forces applied in the direction of a longitudinal axis disposed in the longitudinal surface, or for forces applied in the direction of a line in a plane perpendicular to the longitudinal surface.

Note that while diagram 100 depicts wearable electronics platform 101 disposed in a flat, two-dimensional plane, wearable electronics platform 101 need not be so limited. In some examples, wearable electronics platform 101 is in a relaxed state (e.g., not subject to the application of external forces), or a neutral position. As shown in diagram 130, application of bending forces 109a and 109b can cause wearable electronics platform 101 to encircle or substantially encircle an axis 155, as shown in diagram 150. Further to diagram 150, wearable electronics platform 101 is disposed in a housing 152 subsequent to a fabrication process in which wearable electronics platform 101 is encapsulated by an outer coating or material. As shown in diagram 150, a longitudinal line 157 traverses lengthwise from end to end, and coextensive to a curved surface. Axis 155 can coincide with an orientation of an appendage, such as a forearm, an ankle, a wrist, or the like. According to alternate examples, wearable electronics platform 101 (in housing 152) can be formed to be in a relaxed state (e.g., a neutral position) as depicted in diagram 150. That is, wearable electronics platform 101 can be in a relaxed state or neutral position when configured to encircle or substantially encircle an axis 155.

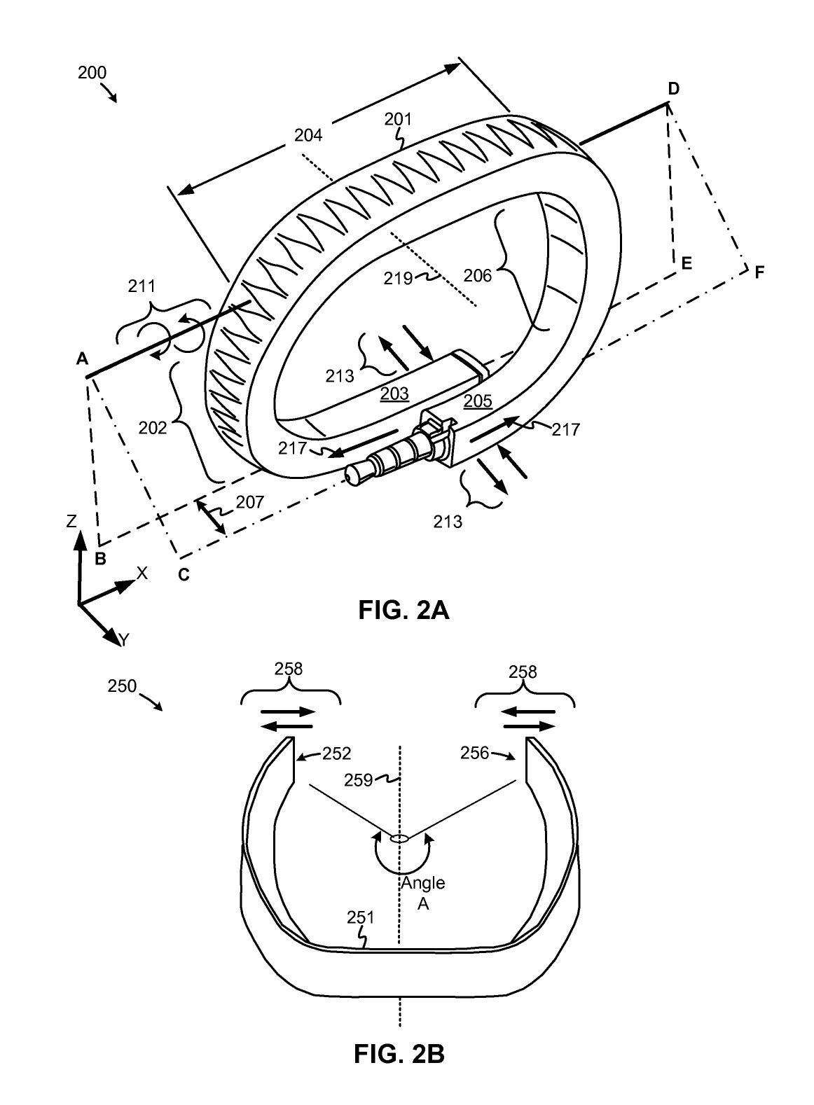

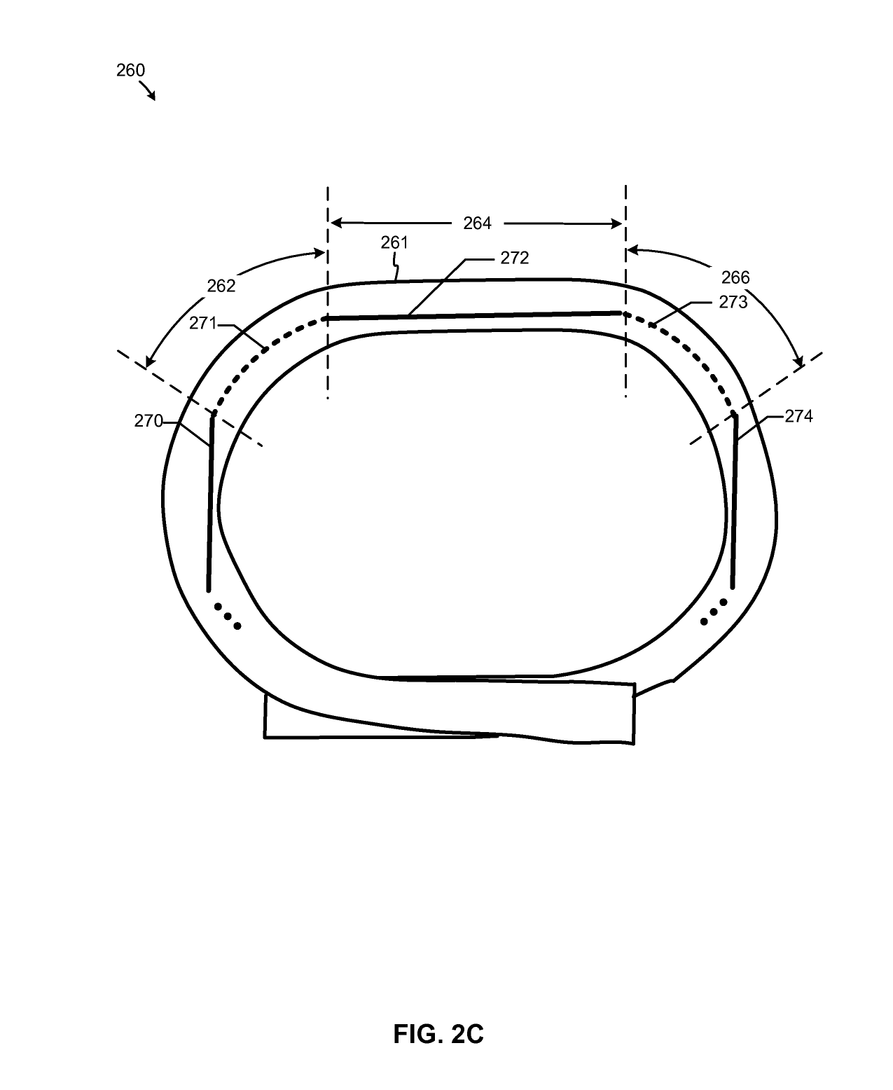

FIGS. 2A and 2B depict other examples of wearable computing devices in which wearable electronics platforms can be disposed, according to some embodiments. Diagram 200 of FIG. 2A depicts a helically-shaped wearable computing device 201 subject to examples of applied forces. As shown, wearable computing device 201 has a central portion 204 coextensive with line A-D. Further, end portion 203 is disposed substantially in a plane defined by A-B-E-D, whereas end portion 205 is disposed substantially in another plane defined by A-C-F-D. In the example shown, intermediate portion 202 is disposed substantially in plane A-B-E-D, and intermediate portion 206 has one end in plane A-B-E-D and transitions to plane A-C-F-D. As shown, end portion 203 is adjacent to end portion 205, but such positioning of end portions 203 and 205 need not limited to that shown in FIG. 2A.

FIG. 2A also depicts forces applied to wearable computing device 201 during its use, such as when a user modifies the shape to wear it on or around an appendage (e.g., around a wrist) or body portion. As shown, forces 217 can be applied to cause end portions 203 and 205 to cause them to separate in different directions along the X-axis (at least initially), which, in turn, can cause portions 203 and 205 to rotate about a line 219. Independently or concurrent to the application of forces 217, at least in some examples, a user can apply forces 213 such that end portions 203 and 205 separate in different directions along the Y-axis (at least initially). Note, too, that forces 213 can apply torsional-like forces 211 to central portion 204.

The wearable electronics platform (not shown) includes interconnect portions, which can include conductors and elastic material, disposed within the housing of wearable computing device 201. At least in some cases, the interconnect portions are configured to provide stress relief under the forces described above for the helical-shaped wearable computing device 201. Therefore, interconnect portions of the wearable electronics platform promotes enhanced reliability of the conductivity between, for example, circuit substrates (not shown).

FIG. 2B is a diagram 250 that depicts a wearable computing device 251 configured to substantially encircle an axis 259, according to some examples. While wearable computing device 251 may be subject to various forces, stresses, and strains, which are not shown, a predominant set of forces are shown as forces 258. Bending forces 258 are typically applied to separate ends 252 and 256 so that a user may attach wearable computing device 251 to an appendage or body portion, such as forehead. As shown, a wearable computing device that substantially encircles an axis need not completely encircle that axis over the range of 360° (e.g., a wearable computing device can substantially encircle an axis by extending its ends between 180° to 359°, such as angle (“A”)270°).

FIG. 2C is a side view that depicts a wearable computing device including an arrangement of interconnect portions and circuit substrates, according to some examples. Diagram 260 is a side view of a wearable computing device 261 having an arrangement of interconnect portions 271 and 273 and circuit substrates 270, 272 and 274. In the example shown, circuit substrates 270, 272 and 274, which can be formed from rigid or semi-rigid materials, are disposed in portions of wearable computing device 261 that are less likely to be subject to forces that causes flexing or bending of the portions. For example, circuit substrate 272 can be disposed in a portion 264 of wearable computing device 261, whereby portion 264 is position to be adjacent to an upper or outside portion of a human wrist. Portion 264 is less likely to be subject to twisting or bending forces. By contrast, interconnect portions 271 and 273 are disposed in a portion 264 and a portion 266, respectively, of wearable computing device 261. In some cases, portions 264 and 266 are configured to flex, for example, when a user is either placing wearable computing device 261 upon the wrist, or removing the device from the wrist.

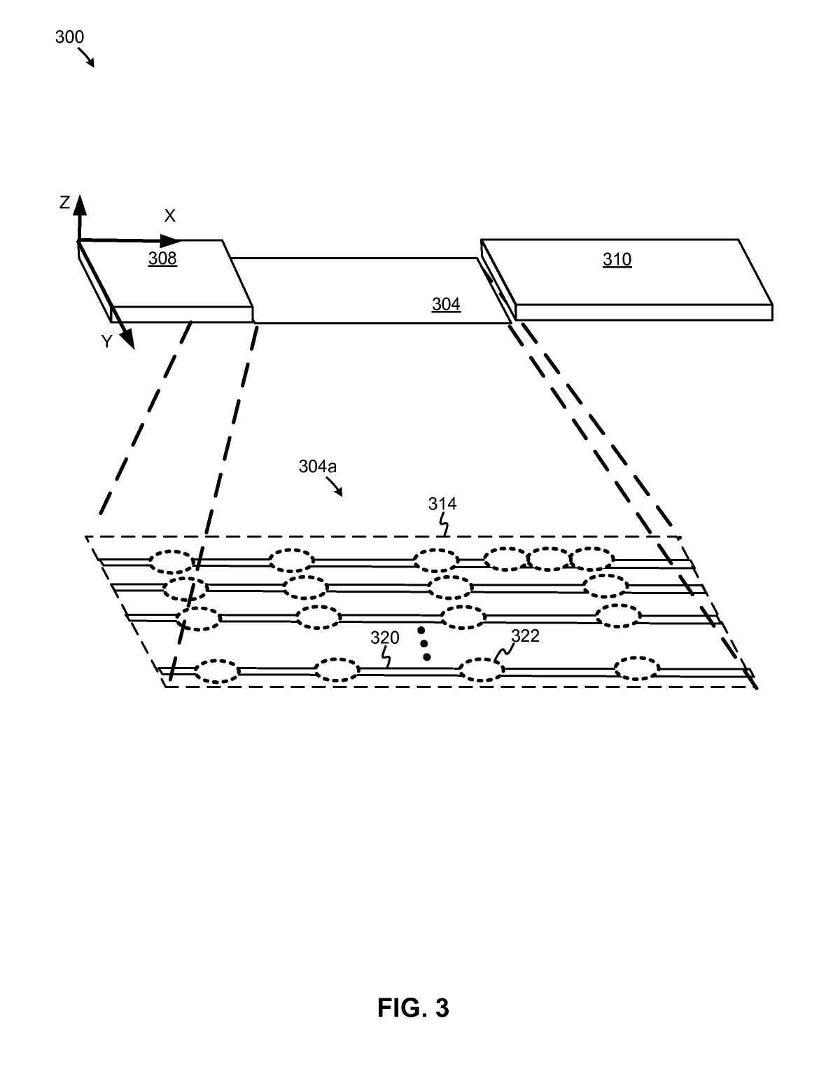

FIG. 3 illustrates an example of an interconnect portion, according to some embodiments. Diagram 300 depicts an interconnect portion 304 coupled between circuit substrate 308 and 310. In an exploded view, interconnect portions 304a is depicted as having a number of conductors 320 disposed in or on a longitudinal surface 314. Conductors 320 are configured to provide conductivity between circuit substrate 308 and 310. According to some examples, at least a subset of conductors 320 includes a conductor 320 that has a stress-relief feature 322. Stress-relief features 322 can be disposed directly adjacent to each other (e.g., contiguous with other stress-relief features 322), or stress-relief features 322 can be disposed at any distance from each other along conductor 320.

According to some examples, a stress-relief feature 322 can be a portion of conductor 320 that deviates in direction (e.g., deviations in the Y-axis) in the longitudinal surface and/or in another direction (e.g., deviations in the Z-axis) as conductor 320 extends between circuit substrate 308 and circuit substrate 310. Stress-relief features 322 in conductor 320 enhance the physical response of conductor 320 to stresses and forces applied, for example, longitudinally. Stress-relief feature 322 can include a curved conductor portion configured to be resilient responsive to the application and removal of stresses. Stress-relief feature 322 can include additional conductive material that is formed in any of a variety of configurations. The additional conductive material of stress-relief feature 322 can be configured to bend, twist, stretch and/or compress responsive to corresponding applied forces to thereby minimize the effects of stress over the entire conductor 320. As such, stress-relief feature 322 can be, for example, stretched or compressed from a neutral position to behave as a stretchable interconnect between circuit substrates 208 and 210 for reducing or eliminating disruptions in conductivity. Note that conductors 320 can include conductors of one or more different types, one or more different sizes, and one or more different shapes or configurations. Similarly, stress-relief features 322 can include conductor portions of different types, different sizes, and/or different shapes or configurations. Note, too, circuit substrate 308 and 310 can be formed in different shapes and different sizes.

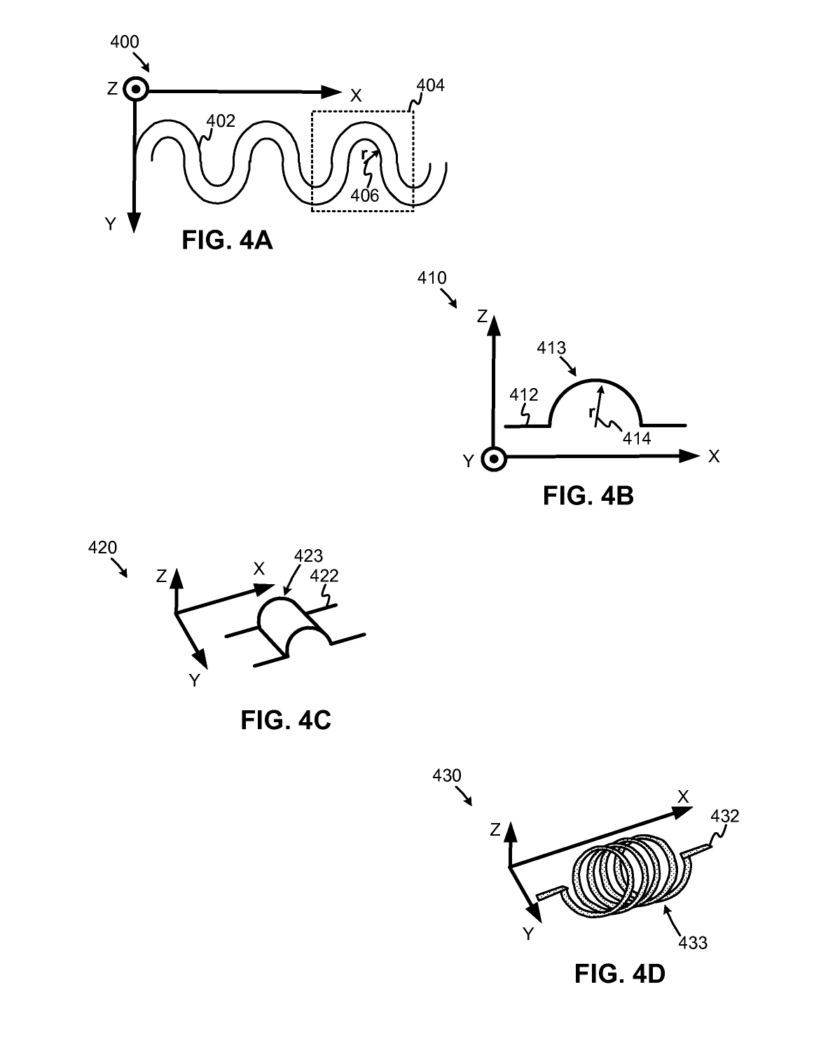

FIGS. 4A to 4D depict examples of stress-relief features, according to some embodiments. Diagram 400 of FIG. 4A depicts a conductor 402 including stress-relief features 404. As shown, stress-relief feature 404 includes curved portions of conductor 402 (i.e., deviations along the Y-axis in the X-Y plane). Stress-relief feature 404 can be configured, for example, as a function of a relaxation radius (“r”) 406, which can be constant or can vary. A according to some embodiments, stress-relief feature 404 can be formed based on a sinusoidal function or a variant thereof.

FIGS. 4B and 4C depict examples of stress-relief features configured to deviate in a plane perpendicular or substantially perpendicular to a longitudinal surface, according to some embodiments. Diagram 410 of FIG. 4B is a side view depicting a stress-relief feature 413 formed in a conductor. As shown, conductive material of stress-relief feature 413 deviates along the Z-axis within the X-Z plane. Stress-relief feature 413 can be configured, for example, as a function of a relaxation radius (“r”) 414, which can be constant or can vary. Diagram 420 of FIG. 4C is a perspective view depicting stress-relief feature 413 of FIG. 4B as stress-relief feature 423. As shown, stress-relief feature 423 is formed in a conductor portion 422. Stress-relief feature 423 can include additional conductive material to accommodate strain in one or more of the X-, Y-, and Z-axes.

While FIGS. 4A to 4C depict examples of stress-relief features having wavy, curved or curvilinear features, stress-relief features of the various embodiments are not so limited. For example, stress-relief feature 404 of FIG. 4A can be formed with sharp features such that conductor 402 has a sawtooth shape. The stress-relief features of the various implementations can be formed in a manufacturing process, such as a semiconductor lithographic process (e.g., metal deposition), or conductors can be physically manipulated to form stress-relief features. For example, a conductor can be folded or bent into a configuration (e.g., accordion-like, or spring-like) to provide additional conductive material that can unfold when stretched and can return back to the originally-folded configuration (e.g., a neutral position) when stress is removed. FIG. 4D is a diagram 430 that depicts an example of a spring-like stress-relief feature 433 formed in a conductor portion 432. Note that while stress-relief feature 433 is depicted as a circular coil, such a stress-relief feature mean not be limited circular-shaped coils.

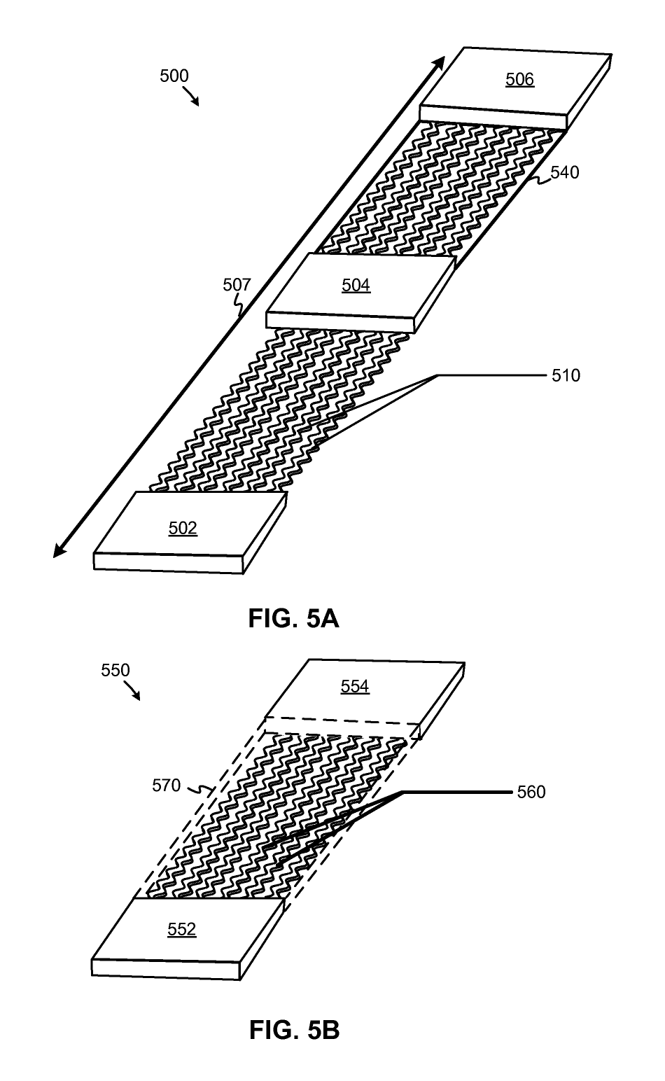

FIGS. 5A to 5B depict examples interconnect portions having stress-relief features, according to some examples. Diagram 500 of FIG. 5A depicts a wearable electronics platform composed of circuit substrates 502, 504, and 506 that are electrically coupled to each other via interconnect portions having conductors 510 with stress-relief features. As shown, conductors 510 include stress-relief features that are shown to include curved portions of conductors 510. The stress-relief features can be configured to relieve stresses along a longitudinal axis 507. In some examples, conductors 510 in their stress-relief features can be formed on a base substrate 540 in accordance with, for example, a lithography process or a semiconductor process. The wearable electronics platform depicted in diagram 500 can be manufactured in a variety of ways. In a first example, conductors 510 can be formed of contiguous conductive material (e.g., extending the length from circuit substrate 502 to circuit substrate 506) upon which contacts on the underside of circuit substrates 502 to 506 can be electrically attached to the conductors 510 underneath. In another example, conductors 510 can be integrated with circuit substrates 502 to 506 such that the interconnections are routed through the circuit substrates. In yet another example, conductors 510 in each interconnection portion can be separate. Thus, the ends of conductors 510 can be attached to one or more edges or portions of the circuit substrates. For instance, one end of a conductor 510 can be connected (e.g., soldered) to circuit substrate 502 and the other end of conductor 510 can be connected to circuit substrate 504.

Diagram 550 of FIG. 5B depicts an example of a wearable electronics platform composed of circuit substrates 522 and 554 that are electrically coupled to each other via an interconnect portion including conductors 560 with stress-relief features, and an elastic material 570, according to some examples. In the example shown, conductors 560 can be encapsulated in elastic material 570. Therefore, the combination of elastic material 570 and the stress-relief features of conductors 560 can absorb or otherwise respond to stresses and strains in a manner that enhances or otherwise preserves connectivity between circuit substrates 552 and 554. In some examples, elastic material 570 can include a viscoelastic material. As such, viscoelastic material 570 can exhibit viscous characteristics and elastic characteristics when stresses are applied and the material undergoes deformation (whether stretching or compressing). Viscoelastic material 570 can be formed with an elastomer suitable to provide stress and strain relief typically applied to wearable devices. In some examples, viscoelastic material 570 can have a modulus less than 100 MPa. In a specific set of examples, viscoelastic material 570 can have a modulus in the range of 3 MPa to 20 MPa (e.g., ≈10 MPa). Note that the interconnection portions can be implemented in a variety of materials. For example, based substrate 540 can be implemented as a fabric (e.g., non-metallic mesh or material) with conductors formed thereon. In other examples, base substrate 540 can be a thin metal or a conductive plate, such as aluminum, etc., upon which conductors can be formed (e.g., by etching). According to various examples, base substrate 540 and conductors 560 can be implemented using a variety of materials.

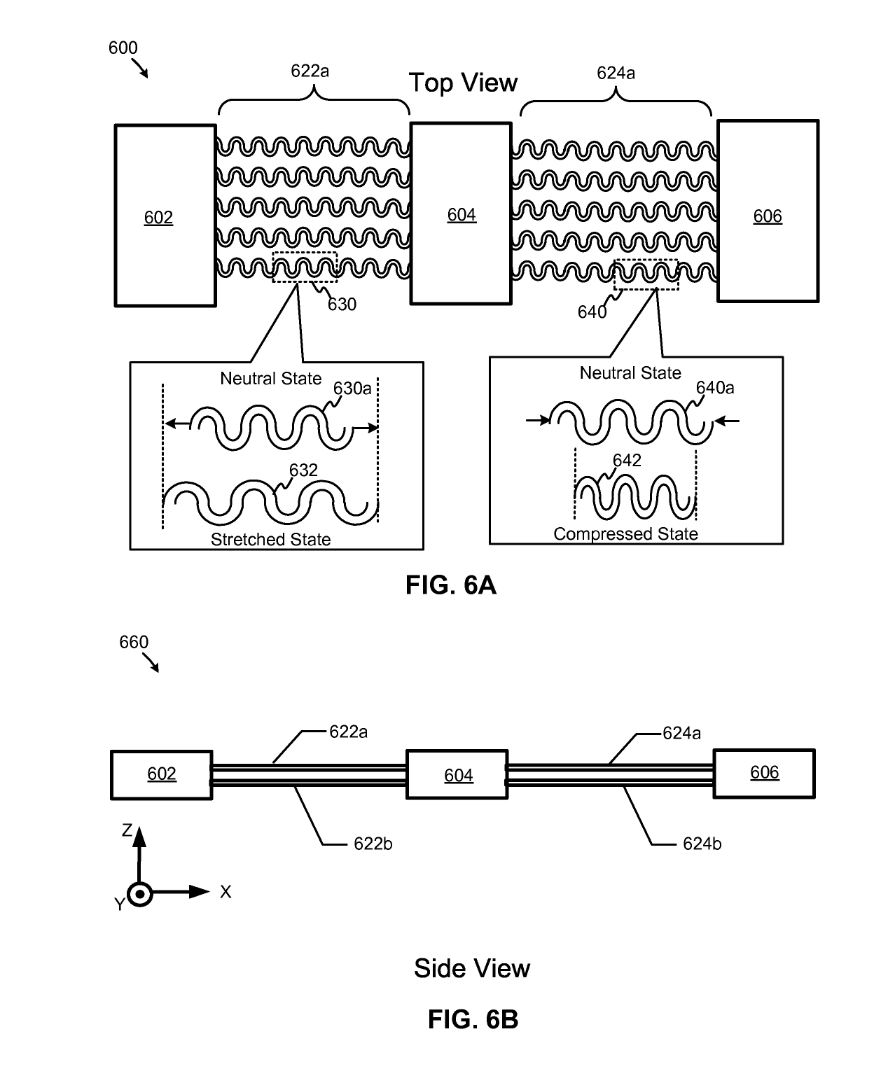

FIGS. 6A and 6B depict a specific example of a wearable electronics platform, according to some examples. Diagram 600 of FIG. 6A is a top view depicting a wearable electronics platform including circuit substrates 602, 604, and 606, and interconnection portion 622a and 624a. To illustrate the stress-relief functionality of stress-relief features of the conductors, consider the following examples. Stress-relief features 630 are depicted in a neutral state 630a in which no external forces are applied. Upon application of a tensile force to one or more ends of the wearable electronics platform (i.e., to the conductors), stress-relief features stretch or otherwise elongate, as shown in stretch state 632. Therefore, stress-relief features 630 include conductive material configured to deform resiliently to reduce or eliminate deleterious effects of strain, thereby enhancing reliability of connectivity. As another example, consider the application of compression forces. As shown, stress-relief features 640 are shown to be in a neutral state 640a when no external forces are applied. Upon application of the compression force to one or more ends of the wearable electronics platform, stress-relief feature 640 can compress into compressed state 642. When the compression forces subside, the previously compressed stress-relief features can return back to their neutral state 640a.

FIG. 6B is a side view depicting multiple layers of interconnect portions that are configured to provide conductivity among circuit substrates, according to some embodiments. Diagram 660 depicts circuit substrates 602, 604, and 606 having a first subset of interconnect portions 622a and 624a disposed in a first layer (e.g., an upper layer), and a second subset of interconnect portions 622b and 624b disposed in a second layer (e.g., a lower layer). Note that while only two layers are depicted in FIG. 6B, any number of multiple layers are possible.

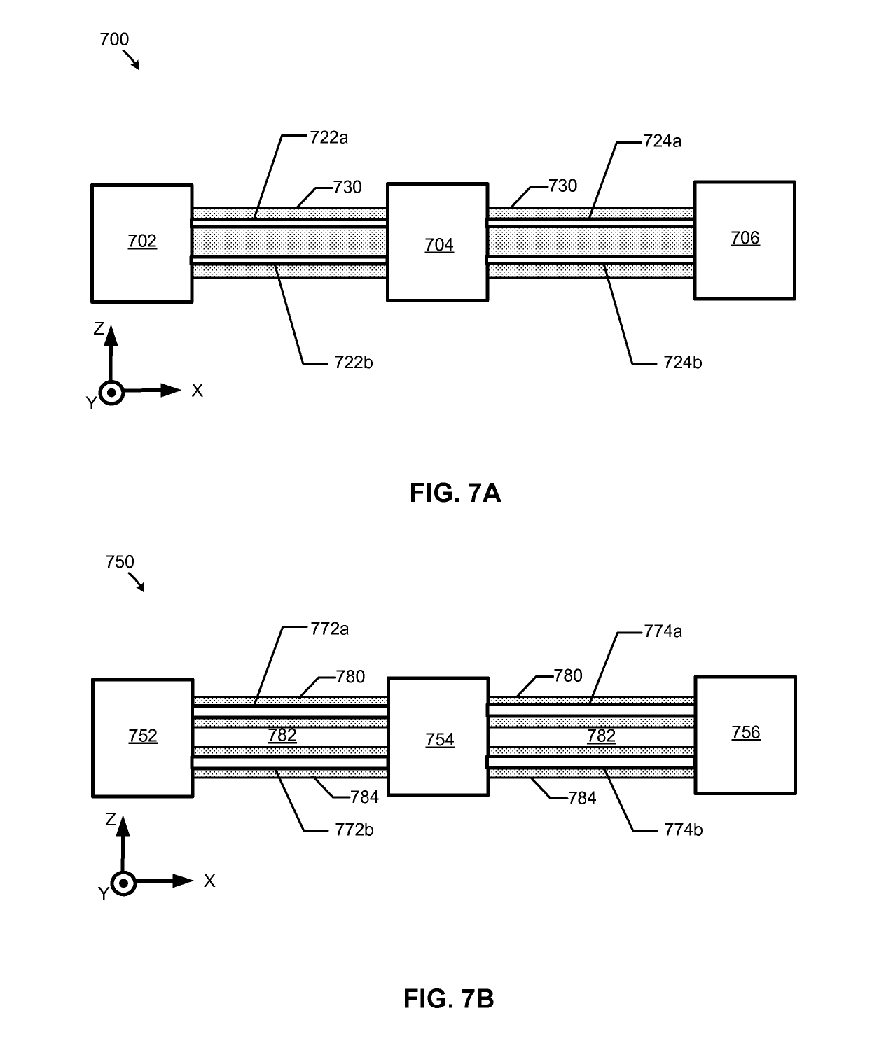

FIGS. 7A and 7B depict specific examples of wearable electronics platforms encapsulated in an elastic material, according to some examples. Diagram 700 of FIG. 7A is a side view depicting a wearable electronics platform including circuit substrates 702, 704, and 706, a first subset of interconnection portion 722a and 724a in a first layer, and a second subset of interconnect portions 722b and 724b in a second layer. Further, both layers of interconnect portions are shown to be encapsulated in an elastic material, such as a viscoelastic material. FIG. 7B is a diagram 750 depicting another example of a wearable electronics platform that includes circuit substrates 752, 754, and 756, an upper subset of interconnection portion 772a and 774a, and a lower subset of interconnect portions 772b and 774b. The first layer of interconnect portions 772a and 774a are shown to be encapsulated in a first encapsulant 780, and the second layer of interconnect portions 772b and 774b are encapsulated in a second encapsulant 784. Encapsulants 780 and 784 can be formed from the same or different elastic material. In some examples, encapsulants 780 and 784 can include a viscoelastic material, such as a elastomer. Further, an interleaved layer 782 can be formed between the layers of encapsulants 780 and 784. In some examples, interleaved layer 782 is an air gap. In alternate examples, interleaved layer 72 can include another elastic or viscoelastic material. In some cases, interleaved layer 72 can include a dielectric material to provide sufficient electrical insulation between the layer of interconnect portions 772a and 774a and the layer of interconnect portions 772b and 774b. Note that the air gap can be formed at a radial distance (or a range of radial distances) from an axis when the wearable electronics platform is to be formed in a shape that encircles an appendage or a body portion, such as a circular or elliptical shape.

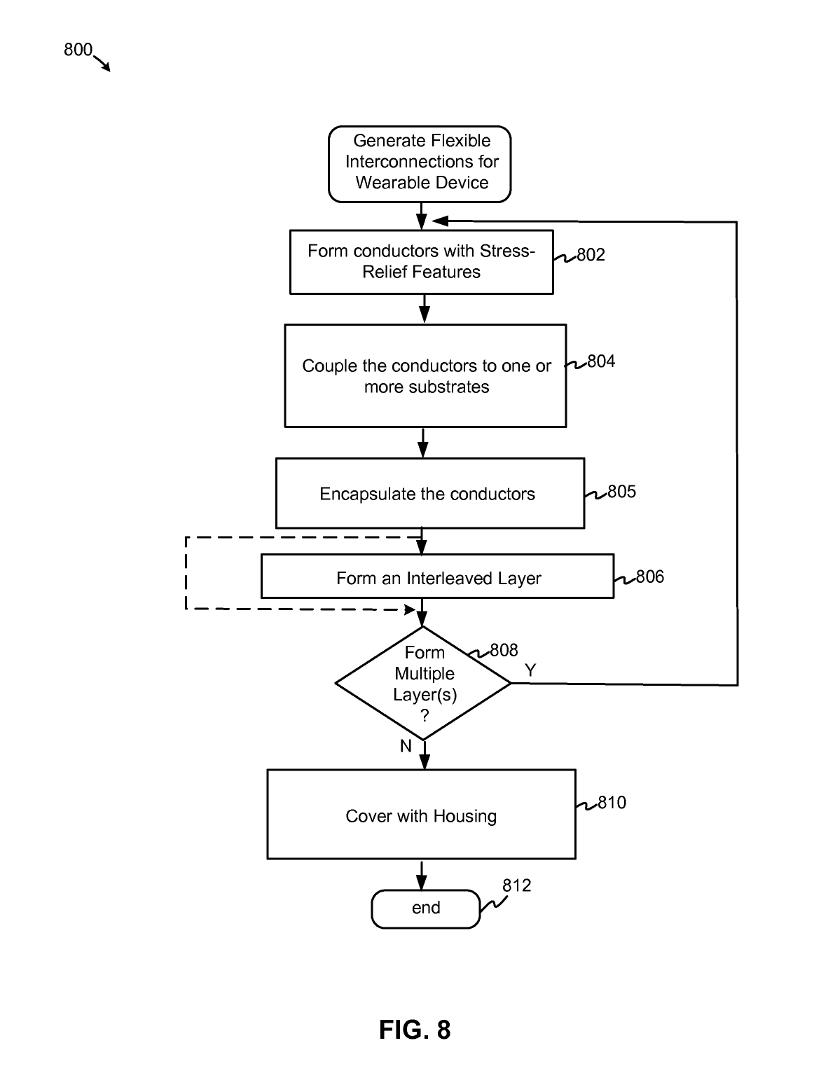

FIG. 8 illustrates an example of a flow for generating flexible interconnections for a wearable device, according to some embodiments. Flow 800 of FIG. 8 is an example flow to manufacture flexible interconnections to form the examples of wearable electronics platforms that are described herein. Flow 800 can begin at 802 by forming conductors with stress-relief features. In some examples, the stress-relief features are formed through lithography processes, by a semiconductor process, or any other type of process for forming conductors. Further, stress-relief features can be formed by folding or bending conductive material to mechanically generate the stress-relief features.

And 804, the conductors coupled to one or more circuit substrates. For example the substrates can be mounted upon continuous conductors or portions of conductors can be attached to the periphery or edges of the circuit substrates. In some cases, the conductors are formed to be integrated with the circuit substrates. At 805, conductors are encapsulated in an elastic or viscoelastic material. At 806, and interleaved layer may be formed between multiple layers. The interleaved layer can be an air gap. A determination is made at 808 whether to form multiple layers. If so, the aforementioned actions are repeated. Otherwise, flow 800 continues to 810, at which a housing is formed over the circuit substrates and conductors. The manufacturing flow ends at 812. The aforementioned flow can be modified within the scope and spirit of the present disclosure.

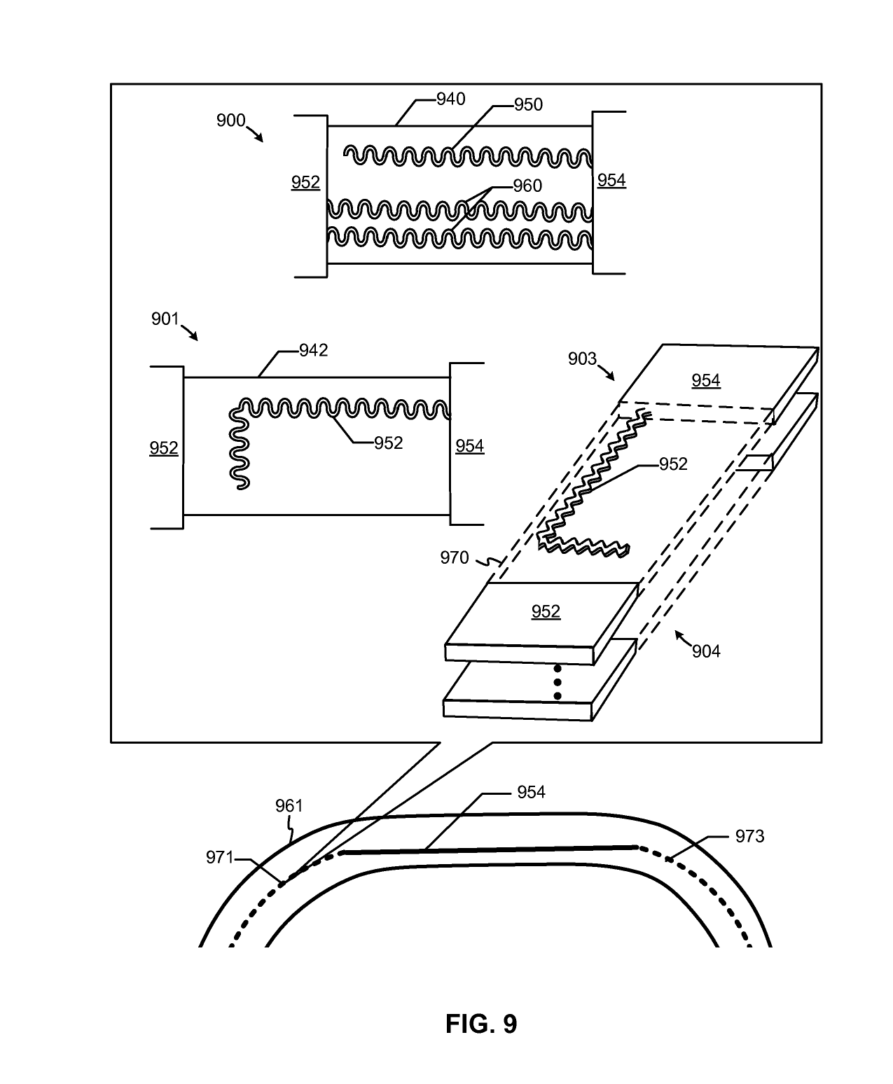

FIG. 9 depicts an antenna implementing one or more conductors including stress-relief features, according to various examples. As shown, a wearable computing device 961 includes interconnect portions 971 and 973, and a circuit substrate 954. FIG. 9 depicts a diagram 900 as a top view of an interconnect portion that can be implemented as interconnect portion 971. As shown in diagram 900, an interconnect portion is disposed between circuit substrates 952 and 954, and includes a base substrate 940. A conductor 950 is an antenna formed with exemplary stress-relief features, according to some embodiments. While conductor 950 is shown as being formed in a linear direction, such an antenna need not be limited to a linear arrangement or formation. In some cases, antenna 950 can be disposed as the only conductor on base substrate 940. In other cases, antenna 950 can be formed adjacent conductors 960, which provide signal connectivity between circuit substrates 952 and 954.

Diagram 901 and 903 are a top view and a perspective view, respectively, of an interconnect portion including an antenna 952. Base substrate 942 is disposed between circuit substrates 952 and 954, and includes a conductor from which antenna 952 is formed. As shown, antenna 952 includes stress-relief features to accommodate stresses associated with the flexing of the flexible interconnect portion. In this configuration, antenna 952 is “L-shaped” (but need not be limited thereto) and configured to receive RF radio signals, such as Bluetooth® or Low Power Bluetooth® radio signals. Note that antenna 952 is shaped to be tuned to receive a range of frequencies that are acceptable representations of, for example, Bluetooth® radio signals as antenna 952 flexes, stretches, compresses, twists, or otherwise is deformed due to stresses (e.g., normal stresses) associated with wearable device 961. Diagram 903 shows an antenna 952 being disposed in an encapsulant or upon an elastic material 970. Further, antenna 952 in diagram 903 can be disposed on a top layer of multiple layers 904, according to some examples.

Although the foregoing examples have been described in some detail for purposes of clarity of understanding, the above-described inventive techniques are not limited to the details provided. There are many alternative ways of implementing the above-described invention techniques. The disclosed examples are illustrative and not restrictive.

What is claimed:

1. A wearable electronics platform comprising:
a plurality of circuit substrates configured to accept a number of electronic devices, the plurality of circuit substrates distributed coextensive with a longitudinal surface having a first end and a second end; and
a plurality of interconnect portions disposed coextensive with the longitudinal surface between subsets of the plurality of circuit substrates, each of the interconnect portions comprising:
a plurality of conductors extending between a first circuit substrate and a second circuit substrate in a subset of the plurality of circuit substrates, each conductor of the plurality of conductors including:
one or more stress-relief features; and
an elastic material encapsulating the plurality of conductors,
wherein the longitudinal surface including the plurality of interconnects and the plurality of circuit substrates is configured to substantially encircle an axis.

2. The wearable electronics platform of claim 1, wherein the elastic material comprises:
a viscoelastic material.

3. The wearable electronics platform of claim 2, wherein the viscoelastic material comprises:
an elastomer.

4. The wearable electronics platform of claim 1, wherein each of the one or more stress-relief features comprises:
a portion of a conductor deviates in direction in the longitudinal surface between the first circuit substrate and the second circuit substrate.

5. The wearable electronics platform of claim 4, wherein the portion of a conductor comprises:
a curved conductor portion.

6. The wearable electronics platform of claim 5, wherein the curved conductor portion provides for stress relief for forces applied in the direction of a longitudinal axis disposed in the longitudinal surface.

7. The wearable electronics platform of claim 5, wherein the curved conductor portion is formed as a function of a sinusoidal function.

8. The wearable electronics platform of claim 1, wherein each of the one or more stress-relief features comprises:
a portion of a conductor deviates in direction in a plane perpendicular to the longitudinal surface between the first circuit substrate and the second circuit substrate.

9. The wearable electronics platform of claim 8, wherein the portion of a conductor is configured to provide stress relief for forces applied in the direction of a line in the plane perpendicular to the longitudinal surface.

10. The wearable electronics platform of claim 1, wherein the elastic material is in a relaxation state absent external forces to the plurality of circuit substrates and/or plurality of interconnect portions, the longitudinal surface that includes the plurality of interconnects and the plurality of circuit substrates formed to encircle the axis in the relaxation state so that the first end and the second end of the longitudinal surface are adjacent.

11. The wearable electronics platform of claim 10, wherein the first end and the second end of the longitudinal surface are adjacent in different planes, wherein the longitudinal surface including the plurality of interconnects and the plurality of circuit substrates is helically-shaped.

12. The wearable electronics platform of claim 1, wherein the plurality of conductors comprise:
conductive material is deposited upon a base substrate during a lithographic process.

13. The wearable electronics platform of claim 1, further comprising:
another plurality of circuit substrates configured to accept a quantity of electronic devices, the another plurality of circuit substrates distributed coextensive with another longitudinal surface; and
another plurality of interconnect portions disposed coextensive with the another longitudinal surface,
wherein portions of the another longitudinal surface are disposed at substantially the same radial distances from portions of the longitudinal surface.

14. The wearable electronics platform of claim 13, further comprising:
an interleaved layer between the another longitudinal surface and the longitudinal surface.

15. The wearable electronics platform of claim 13, further comprising:
an air gap between the another longitudinal surface and the longitudinal surface.

16. The wearable electronics platform of claim 1, wherein the elastic material comprises:
a viscoelastic material having a modulus in the range of 3 MPa to 20 MPa.

17. A method comprising:
selecting a first circuit substrate and a second circuit substrate that include a number of electronic devices;
forming a plurality of conductors extending between the first circuit substrate and the second circuit substrate;
forming for each conductor of the plurality of conductors a stress-relief feature;
coupling the plurality of conductors to the first circuit substrate and to the second circuit substrate; and
encapsulating the plurality of conductors in a viscoelastic material.

18. The method of claim 17, wherein forming the stress-relief feature comprises.
depositing a conductive material on a base substrate such that portions of the conductive material deviate in direction in a longitudinal surface between the first circuit substrate and the second circuit substrate

19. The method of claim 17, further comprising:
forming another plurality of circuit substrates configured to accept other electronic devices; and
forming another plurality of conductors disposed at substantially a same radial distance from the plurality of conductors.

20. The method of claim 19, further comprising:
forming an air gap at a radial distance from an axis between the another plurality of conductors and the plurality of conductors; and
forming at least one conductor extending from the first circuit substrate to implement an antenna with stress-relief features.
